(19) United States
(12) Patent Application Publication
(10) Pub. No.: US 2025/0234731 A1
(43) Pub. Date: Jul. 17, 2025

(54) DISPLAY DEVICE, METHOD OF MANUFACTURING THE SAME AND ELECTRONIC DEVICE INCLUDING THE SAME

(71) Applicant: SAMSUNG DISPLAY CO., LTD., YONGIN-SI (KR)

(72) Inventors: HYUN KIM, Yongin-si (KR); KAP SOO YOON, Yongin-si (KR); WOOGEUN LEE, Yongin-si (KR); JIN-WON LEE, Yongin-si (KR); SEUNG-HA CHOI, Yongin-si (KR); SEUL-KI KIM, Yongin-si (KR); JEONGJU PARK, Yongin-si (KR)

(21) Appl. No.: 18/978,596

(22) Filed: Dec. 12, 2024

(30) Foreign Application Priority Data
Jan. 17, 2024 (KR) 10-2024-0007329

(51) Int. Cl. H10K 59/131; H10K 59/12; H10K 59/121

(52) U.S. Cl. CPC H10K 59/131; H10K 59/1201; H10K 59/1213

(57) ABSTRACT

A display device includes a first buffer layer disposed on a substrate. An etch stop layer is disposed on the first buffer layer. A second buffer layer is disposed on the etch stop layer. The second buffer layer includes a first hole exposing at least a portion of an upper surface of the etch stop layer. An active layer is disposed on the second buffer layer. The active layer includes a conductive area and a second hole exposing the first hole. An inorganic layer is disposed on the active layer. The inorganic layer fills the first hole and the second hole.

### CROSS-REFERENCE TO RELATED APPLICATION(S)

This application claims priority under 35 U.S.C. § 119 to Korean Patent Application No. 10-2024-0007329, filed on Jan. 17, 2024 in the Korean Intellectual Property Office, the disclosure of which is incorporated by reference in its entirety herein.

### 1. TECHNICAL FIELD

Embodiments relate to a display device. More particularly, embodiments relate to the display device and a method of manufacturing the display device.

### 2. DISCUSSION OF RELATED ART

A display device is a device that displays images to provide visual information to users. The importance of display devices which serve as a connecting medium between users and information has increased along with the development of information technology. For example, the usage of display devices such as liquid crystal display devices (LCD) and organic light-emitting display devices (OLED) is increasing.

A display device may include a partially doped active layer and a plurality of layers disposed around the active layer. When manufacturing a display device, a portion of the active layer may be etched. When the etching process is performed, a step may be formed between the active layer and layers disposed around the active layer. If the step is large, moisture may easily penetrate into the display device. Accordingly, the reliability of the display device may decrease.

### SUMMARY

Embodiments provide a display device with an increased reliability.

According to an embodiment of the present disclosure, a display device includes a first buffer layer disposed on a substrate. An etch stop layer is disposed on the first buffer layer. A second buffer layer is disposed on the etch stop layer. The second buffer layer includes a first hole exposing at least a portion of an upper surface of the etch stop layer. An active layer is disposed on the second buffer layer. The active layer includes a conductive area and a second hole exposing the first hole. An inorganic layer is disposed on the active layer. The inorganic layer fills the first hole and the second hole.

In an embodiment, the etch stop layer may include a material different from a material of the second buffer layer.

In an embodiment, the etch stop layer may include at least one compound selected from a group consisting of a metal oxide, a silicon (Si), a silicon nitride (SiNₓ), and a silicon oxynitride (SiNₓO_{y}).

In an embodiment, the second buffer layer may include a silicon oxide (SiOₓ).

In an embodiment, the first buffer layer may include a third buffer layer disposed on the substrate and a fourth buffer layer disposed on the etch stop layer, and the etch stop layer may include a material different from a material of the fourth buffer layer.

In an embodiment, the fourth buffer layer may include a silicon oxide.

In an embodiment, a sum of a depth of the first hole and a depth of the second hole may be less than or equal to about 30 nm.

In an embodiment, the etch stop layer may directly contact the inorganic layer through the first hole and the second hole.

In an embodiment, the inorganic layer may cover an end of the active layer that is exposed by the first hole and the second hole, and an end of the second buffer layer.

In an embodiment, around the end of the active layer and the end of the second buffer layer, the inorganic layer may directly contact an upper surface of the active layer, a side surface of the active layer, a side surface of the second buffer layer, and a portion of the upper surface of the etch stop layer.

In an embodiment, the display device may further include a gate insulation layer disposed on the active layer, a gate electrode disposed on the gate insulation layer, and a contact electrode disposed on the gate insulation layer and directly contacting a portion of the conductive area.

In an embodiment, the gate insulation layer includes a third hole exposing the second hole and a portion of an upper surface of the active layer. A size of the third hole may be greater than a size of the second hole.

In an embodiment, each of the first hole and the second hole may be located between the gate electrode and the contact electrode.

According to an embodiment of the present disclosure, a method of manufacturing a display device includes forming a first buffer layer on a substrate. An etch stop layer is formed on the first buffer layer. A second buffer layer is formed on the etch stop layer. The second buffer layer includes a first hole exposing a portion of an upper surface of the etch stop layer. An active layer is formed on the second buffer layer. The active layer includes a second hole exposing the first hole. An inorganic layer is formed on the active layer. The inorganic layer fills the first hole and the second hole.

In an embodiment, the forming of the second buffer layer may include forming a preliminary buffer layer on the etch stop layer. The first hole is formed by removing a portion of the preliminary buffer layer. The forming of the active layer may include forming a preliminary active layer on the preliminary buffer layer. The second hole is formed by removing a portion of the preliminary active layer.

In an embodiment, the forming of the first hole may include removing a portion of the preliminary buffer layer in a thickness direction to expose the upper surface of the etch stop layer by spraying an etching gas on the preliminary buffer layer.

In an embodiment, the forming of the first hole may be performed after the forming of the second hole.

In an embodiment, the method may further include forming a gate insulation layer on the preliminary active layer. The gate insulation layer includes a gate hole exposing a portion of an upper surface of the preliminary active layer. A gate electrode is formed on the gate insulation layer. A contact electrode is formed on the gate insulation layer. The contact electrode is spaced apart from the gate electrode

In an embodiment, a size of gate hole is less than a size of the second hole.

In an embodiment, the method may further include forming a third hole by expanding the gate hole and a size of the third hole may be greater than a size of the second hole.

According to an embodiment of the present disclosure, an electronic device includes a display device and a power supply. The display device includes a first buffer layer disposed on a substrate. An etch stop layer is disposed on the first buffer layer. A second buffer layer is disposed on the etch stop layer. The second buffer layer includes a first hole exposing at least a portion of an upper surface of the etch stop layer. An active layer is disposed on the second buffer layer. The active layer includes a conductive area and a second hole exposing the first hole. An inorganic layer is disposed on the active layer. The inorganic layer fills the first hole and the second hole. The power supply provides power to the display device.

In a display device according to an embodiment of the present disclosure, the display device may include a first buffer layer disposed on a substrate, an etch stop layer disposed on the first buffer layer, a second buffer layer disposed on the etch stop layer and in which a first hole is defined, and disposed on the second buffer layer, an active layer in which a second hole is defined, and an inorganic layer filling the first hole and the second hole. As the first hole does not penetrate the etch stop layer in a thickness direction and exposes at least a portion of the upper surface of the etch stop layer, a formation of a moisture permeable path through which external moisture flows into the inorganic layer filling the first hole may be blocked. Accordingly, defects in the display device may be prevented and a reliability of the display device may be increased.

### BRIEF DESCRIPTION OF THE DRAWINGS

Illustrative, non-limiting embodiments of the present disclosure will be more clearly understood from the following detailed description in conjunction with the accompanying drawings.

FIG. 1 is a plan view illustrating a display device according to an embodiment of the present disclosure.

FIG. 2 is a block diagram illustrating a driving of the display device of FIG. 1 according to an embodiment of the present disclosure.

FIG. 3 is a circuit diagram illustrating a pixel of FIG. 1 according to an embodiment of the present disclosure.

FIG. 4 is a plan view illustrating a pixel of FIG. 1 according to an embodiment of the present disclosure.

FIG. 5 is a cross-sectional view of a pixel taken along a line I-I′ of FIG. 4 according to an embodiment of the present disclosure.

FIG. 6 is a cross-sectional view of a pixel taken along a line II-II′ of FIG. 4 according to an embodiment of the present disclosure.

FIGS. 7, 8, 10, 12, 13, 16, and 20 are plan views of a method of manufacturing the display device of FIG. 1 according to embodiments of the present disclosure.

FIGS. 9, 11, 14, 15, 17, 18, 19, 21, 22, and 23 are cross-sectional views of a method of manufacturing the display device of FIG. 1 according to embodiments of the present disclosure.

FIG. 24 is a block diagram illustrating an electronic device according to an embodiment.

### DETAILED DESCRIPTION OF EMBODIMENTS

Hereinafter, display devices in accordance with embodiments of the present disclosure will be described in more detail with reference to the accompanying drawings. The same reference numerals are used for the same components in the drawings, and redundant descriptions of the same components may be omitted for economy of explanation.

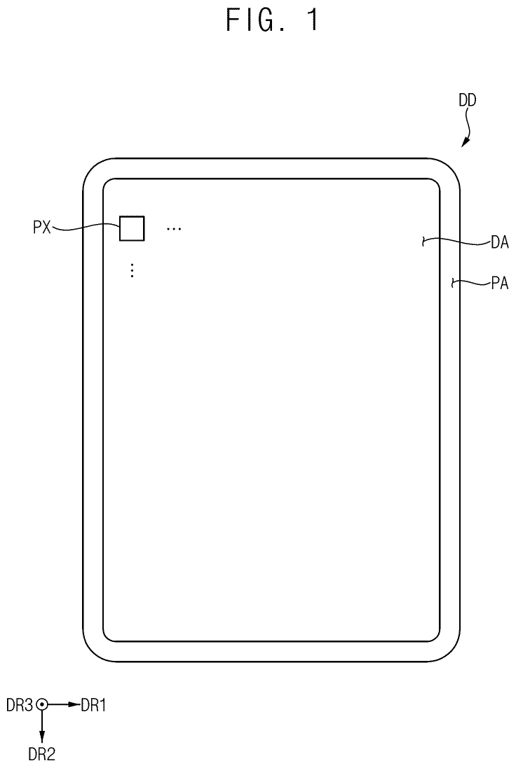

FIG. 1 is a plan view illustrating a display device according to an embodiment of the present disclosure.

Referring to FIG. 1, a display device according to an embodiment of the present disclosure may include a display area DA and a peripheral area PA.

In this specification, a plane may be defined in a first direction DR1 and a second direction DR2. For example, in an embodiment the second direction DR2 may be perpendicular to the first direction DR1. In addition, in an embodiment a third direction DR3 may be perpendicular to the plane. However, embodiments of the present disclosure are not necessarily limited thereto and the first to third directions DR1, DR2, DR3 may cross each other at various different angles.

The display area DA may be defined as an area that displays an image by generating light or adjusting a transmittance of light provided from an external light source. At least one pixel PX may be disposed in the display area DA. The pixel PX may emit light.

In an embodiment, a plurality of pixels PX may be arranged in a matrix form. For example, the plurality of pixels PX may be arranged in the first direction DR1 and the second direction DR2. In addition, the pixel PX may include a plurality of sub-pixels that emit light of different colors. For example, in an embodiment the sub-pixels may include a red sub-pixel that emits red light, a green sub-pixel that emits green light, and a blue sub-pixel that emits blue light. However, embodiments of the present disclosure are not necessarily limited thereto and the number of the different sub-pixels and the colors emitted by the sub-pixels may vary.

The peripheral area PA may be defined as an area that does not display images. The peripheral area PA may be located around the display area DA. For example, the peripheral area PA may surround at least a portion of the display area DA (e.g., in the first and second directions DR1, DR2).

In an embodiment, a driver may be disposed in the peripheral area PA. For example, the driver may drive the pixel PX. The driver may include a data driver, a gate driver, a light emission driver, a power supply voltage generator, and a timing controller. The pixel PX may emit light based on a signal received from the driver.

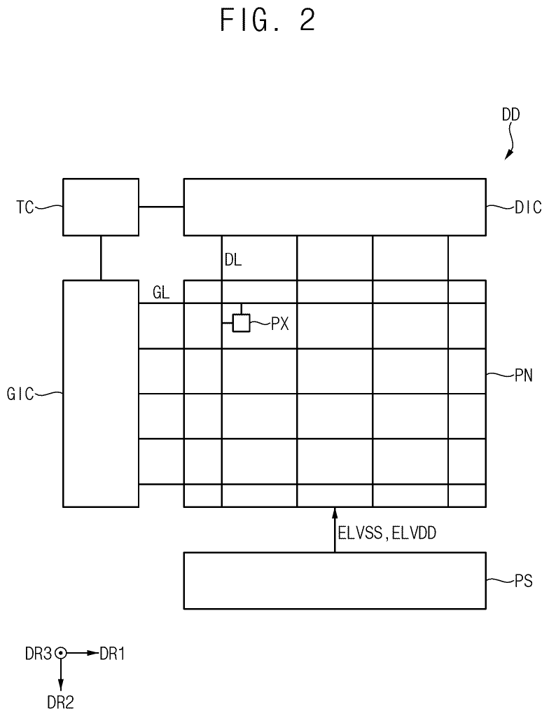

FIG. 2 is a block diagram illustrating a driving of the display device of FIG. 1.

Referring to FIG. 2, the display device DD may include a display panel PN, a data driver DIC, a gate driver GIC, and a controller TC.

In an embodiment, the controller TC may receive a data signal and an input control signal from an external device. The controller TC may transmit a data signal to the data lines DL and gate lines GL. In an embodiment, the image data signal may include a red (R) image data, a green (G) image data, and a blue (B) image data. The controller TC may generate a data signal and a gate signal based on the image data signal and the input control signal.

A plurality of pixels PX and signal lines applying electrical signals to the pixels may be disposed on the display panel PN. In an embodiment, the signal lines may include gate lines GL extending in the first direction DR1 and data lines DL extending in the second direction DR2.

The gate lines GL are arranged to be spaced apart from each other along the second direction DR2 and may transmit gate signals to the pixels PX. The data lines DL are arranged to be spaced apart from each other along the first direction DR1 and may transmit data signals to the pixels PX. In an embodiment, each of the pixels PX may be connected to at least one corresponding gate line among the gate lines GL and at least one corresponding data line among the data lines DL.

In an embodiment, the data driver DIC is connected to the data lines DL and may supply the data signal to the data lines DL in response to a data control signal provided from the controller TC.

In an embodiment, the gate driver GIC may be connected to the gate lines GL, generate the gate signal in response to a gate control signal provided from the controller TC, and sequentially supply the gate signal to the gate lines GL.

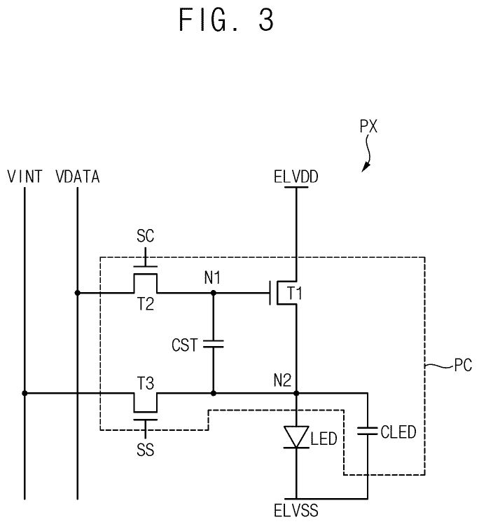

In an embodiment, a power supplier PS may be arranged to be spaced apart from each other along the second direction DR2 of the display panel PN. The power supplier PS may transmit a driving voltage (e.g., ELVDD of FIG. 3) so that the display panel PN may be driven. In an embodiment, the power supplier PS may also transmit a common voltage (e.g., ELVSS of FIG. 3).

FIG. 3 is a circuit diagram illustrating a pixel of FIG. 1.

Referring to FIG. 3, the pixel PX may include a pixel circuit PC and a light-emitting element LED electrically connected to the pixel circuit PC. In an embodiment, the pixel circuit PC may include first, second, and third transistors T1, T2, and T3, a storage capacitor CST, and a light-emitting capacitor CLED. However, embodiments of the present disclosure are not necessarily limited thereto.

The first transistor T1 may include a first electrode, a gate electrode, and a second electrode. The gate electrode of the first transistor T1 may be connected to the first node N1. The driving voltage ELVDD may be applied to the first electrode of the first transistor T1. The second electrode of the first transistor T1 may be connected to the second node N2. In an embodiment, the first transistor T1 may receive the driving voltage ELVDD from a driving voltage line in response to the voltage of the first node N1 and supply a driving current to the light-emitting element LED. For example, the first transistor T1 may be a driving transistor for driving the light-emitting element LED.

The second transistor T2 may include a first electrode, a gate electrode, and a second electrode. A first scan signal SC may be applied to the gate electrode of the second transistor T2. A data voltage VDATA may be applied to the first electrode of the second transistor T2. The second electrode of the second transistor T2 may be connected to the first node N1. In an embodiment, the second transistor T2 is turned on by the first scan signal SC and the second transistor T2 may electrically connect the data line providing the data voltage VDATA to the first node N1. For example, the second transistor T2 may be a switching transistor.

The third transistor T3 may include a first electrode, a gate electrode, and a second electrode. A second scan signal SS may be applied to the gate electrode of the third transistor T3. An initialization voltage VINT may be applied to the first electrode of the third transistor T3. The second electrode of the third transistor T3 may be connected to the second node N2. In an embodiment, the third transistor T3 is turned on by the second scan signal SS to electrically connect an initialization voltage line providing the initialization voltage VINT to the second node N2. For example, the third transistor T3 may be an initialization transistor.

The storage capacitor CST may include a first electrode and a second electrode. The first electrode of the storage capacitor CST may be connected to the first node N1. The second electrode of the storage capacitor CST may be connected to the second node N2. The storage capacitor CST may store a difference voltage between a gate voltage and a source voltage of the first transistor T1.

The light-emitting capacitor CLED may include a first electrode and a second electrode. The first electrode of the light-emitting capacitor CLED may be connected to the second node N2. The second electrode of the light-emitting capacitor CLED may be connected to the second electrode of the light-emitting element LED. In an embodiment, the light-emitting capacitor CLED may maintain a voltage between both ends of the light-emitting element LED to be constant, thereby enabling the light-emitting element LED to display constant luminance.

The light-emitting element LED may include a first electrode (e.g., an anode electrode) and a second electrode (e.g., a cathode electrode). The first electrode of the light-emitting element LED may be connected to the second node N2. A common voltage ELVSS may be applied to the second electrode of the light-emitting element LED. The light-emitting element LED may emit light with a luminance corresponding to the driving current provided from the pixel circuit PC.

However, embodiments of the present disclosure are not necessarily limited to an embodiment shown in FIG. 3 which includes the pixel PX having three transistors (e.g., the first, second, and third transistors T1, T2, and T3), the storage capacitor CST, and the light-emitting capacitor CLED and one or more of these elements may vary.

In addition, embodiments of the present disclosure are not necessarily limited to an embodiment shown in FIG. 3 in which the pixel PX includes one light-emitting element LED. For example, in some embodiments, one pixel PX may include two or more light-emitting elements.

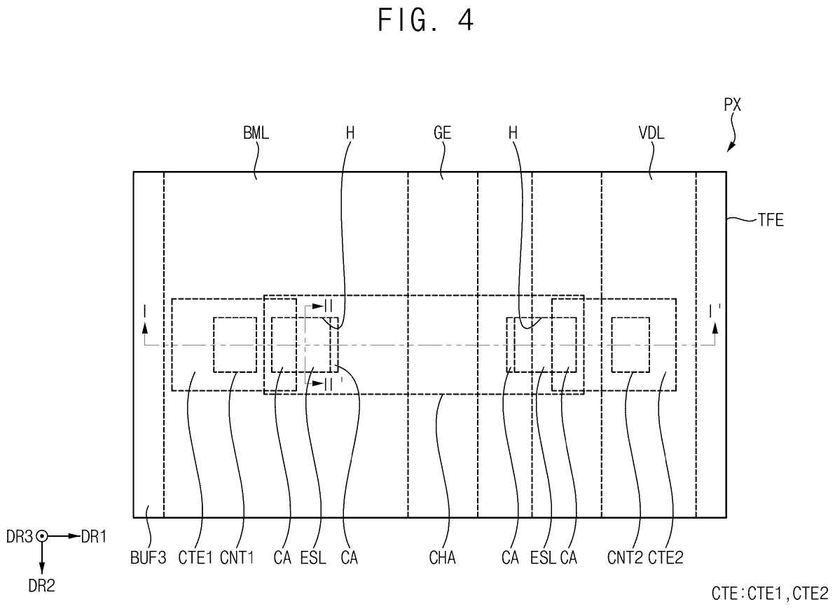

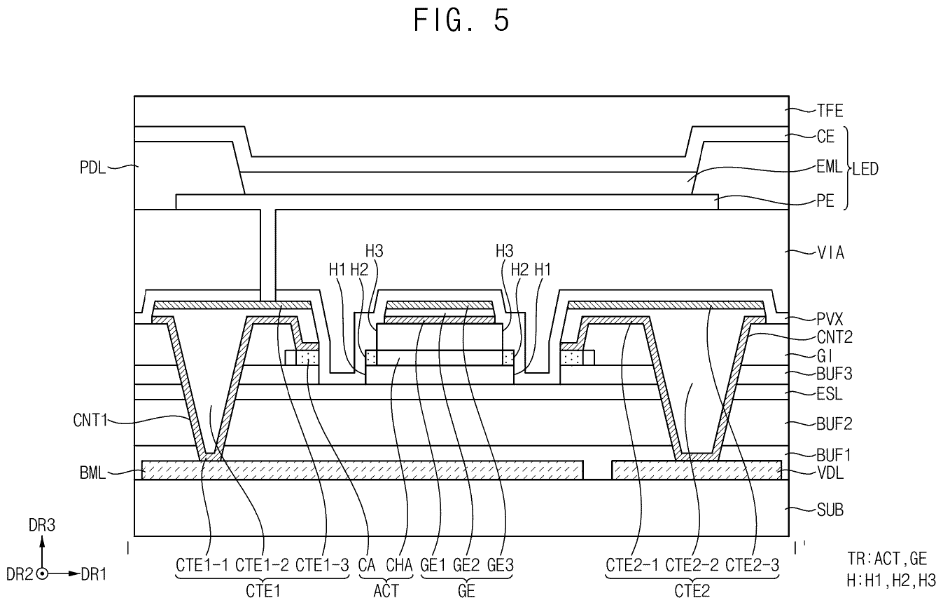

FIG. 4 is a plan view illustrating a pixel of FIG. 1. FIG. 5 is a cross-sectional view illustrating a cross-section taken along a line I-I′ of FIG. 4.

Referring to FIGS. 4 and 5, in an embodiment the display device DD of FIG. 1 may include a substrate SUB, a light blocking layer BML, a driving voltage line VDL, a first buffer layer BUF1, a second buffer layer BUF2, an etch stop layer ESL, a third buffer layer BUF3, a transistor TR, a gate insulation layer GI, a contact electrode CTE, an inorganic layer PVX, a via layer VIA, the light-emitting element LED, a pixel define layer PD and an encapsulation layer TFE. The pixel PX may include the transistor TR and the light-emitting element LED.

In an embodiment, the substrate SUB may include a glass substrate, a metal substrate, a plastic substrate, and the like. However, embodiments of the present disclosure are not necessarily limited to this, and the substrate SUB may be an inorganic layer, an organic layer, or a composite material layer in some embodiments.

The light blocking layer BML may be disposed on the substrate SUB (e.g., disposed directly thereon in the third direction DR3). In an embodiment, the light blocking layer BML may include an aluminum (Al), a platinum (Pt), a palladium (Pd), a silver (Ag), a magnesium (Mg), a gold (Au), a nickel (Ni), a neodymium (Nd), and an iridium (Ir), a chromium (Cr), a lithium (Li), a calcium (Ca), a molybdenum (Mo), a titanium (Ti), a tungsten (W), a copper (Cu), and the like. These materials may be used alone or in combination with each other. For example, the light blocking layer BML may be a single layer including the molybdenum. In addition, the light blocking layer BML may have a double-layer structure in which a first layer including the molybdenum and a second layer including the titanium are stacked, or a triple-layer structure in which a first layer including the titanium, a second layer including the aluminum, and a third layer including the titanium are stacked. However, embodiments of the present disclosure are not necessarily limited thereto.

The driving voltage line VDL may be disposed on the substrate SUB (e.g., disposed directly thereon in the third direction DR3). The driving voltage line VDL may transmit the driving voltage (e.g., the driving voltage ELVDD of FIG. 3) to the pixel PX.

In an embodiment, the driving voltage line VDL may include the same material as the light blocking layer BML. In addition, the driving voltage line VDL may be disposed on a same layer as the light blocking layer BML. In an embodiment, the driving voltage line VDL may be spaced apart from the light blocking layer BML in the first direction DR1 in a plan view. Different types of electrical signals may be applied to the driving voltage line VDL and the light blocking layer BML.

The first buffer layer BUF1 may be disposed on the substrate SUB (e.g., disposed directly thereon in the third direction DR3). For example, the first buffer layer BUF1 may cover the light blocking layer BML and the driving voltage line VDL. The first buffer layer BUF1 may prevent impurities such as oxygen and a moisture from penetrating into the upper portion of the substrate SUB. In addition, the first buffer layer BUF1 may increase a flatness of a surface of the substrate SUB when the surface of the substrate SUB is not uniform.

In an embodiment, the first buffer layer BUF1 may include an inorganic insulation material. For example, the inorganic insulation material may include a silicon nitride (SiNₓ).

The second buffer layer BUF2 may be disposed on the first buffer layer BUF1 (e.g., disposed directly thereon in the third direction DR3). For example, the second buffer layer BUF2 may cover the first buffer layer BUF1. The second buffer layer BUF2 may include an inorganic insulation material. For example, in an embodiment the inorganic insulation material may include a silicon oxide (SiOₓ). However, embodiments of the present disclosure are not necessarily limited thereto.

In an embodiment, the second buffer layer BUF2 may include a material different from the first buffer layer BUF1. For example, the second buffer layer BUF2 may include a silicon oxide, and the first buffer layer BUF1 may include a silicon nitride. However, embodiments of the present disclosure are not necessarily limited thereto, and the second buffer layer BUF2 may include a same material as the first buffer layer BUF1 in some embodiments.

The etch stop layer ESL may be disposed on the second buffer layer BUF2 (e.g., disposed directly thereon in the third direction DR3). For example, the etch stop layer ESL may cover the second buffer layer BUF2.

In an embodiment, the etch stop layer ESL may include a silicon nitride (e.g., SiON).

For example, in an embodiment, the etch stop layer ESL may include a silicon oxynitride (SiNₓO_{y}).

In an embodiment, the etch stop layer ESL may include a silicon (Si), a metal oxide, and the like. These materials may be used alone or in combination with each other. For example, in an embodiment the etch stop layer ESL may include at least one material selected from a group consisting of a metal oxide, a silicon (Si), a silicon nitride (SiNₓ) and a silicon oxynitride (SiNₓO_{y}). For example, the metal oxide may include an aluminum oxide (AlOₓ).

In an embodiment, the etch stop layer ESL may include a material different from the second buffer layer BUF2. For example, the etch stop layer ESL may include a silicon nitride, and the second buffer layer BUF2 may include a silicon oxide. In an embodiment, the etch stop layer ESL may include a silicon oxynitride, and the second buffer layer BUF2 may include silicon oxide. However, embodiments of the present disclosure are not necessarily limited thereto.

The third buffer layer BUF3 may be disposed on the etch stop layer ESL (e.g., disposed directly thereon in the third direction DR3). The third buffer layer BUF may cover a portion of the etch stop layer ESL. A first hole H1 exposing a portion of an upper surface of the etch stop layer ESL may be defined in the third buffer layer BUF.

In an embodiment, the third buffer layer BUF3 may include an inorganic insulation material. For example, the inorganic insulation material may include a silicon oxide.

In an embodiment, the third buffer layer BUF3 may include a material different from the etch stop layer ESL. For example, in an embodiment the third buffer layer BUF3 may include a silicon oxide, and the etch stop layer ESL may include a silicon oxynitride.

In an embodiment, in an etching process to form the first hole H1, the etching gas with a lower etch selectivity for a material included in the etch stop layer ESL than a material included in the third buffer layer BUF3 may be used. For example, in a same process using the etching gas, the etch rate of the etch stop layer ESL may be less than the etch rate of the third buffer layer BUF3. Accordingly, while the first hole H1 is formed in the third buffer layer BUF3, the etch stop layer ESL may not be etched, and a hole penetrating the etch stop layer ESL may not be formed.

The transistor TR may be disposed on the third buffer layer BUF3. In an embodiment, the transistor TR may include an active layer ACT and a gate electrode GE. The transistor TR may allow current to flow according to the signal of the gate electrode GE.

The active layer ACT may be disposed on the third buffer layer BUF (e.g., disposed directly thereon in the third direction D3). In an embodiment, the active layer ACT may include an oxide semiconductor. For example, in an embodiment the oxide semiconductor may include an indium (In), a gallium (Ga), a tin (Sn), a zirconium (Zr), a vanadium (V), a hafnium (Hf), a cadmium (Cd), a germanium GE, and a chromium, a titanium, a zinc (Zn), and the like. These materials may be used alone or in combination with each other.

However, embodiments of the present disclosure are not necessarily limited thereto, and the active layer ACT may include a silicon semiconductor or an organic semiconductor. For example, the silicon semiconductor may include an amorphous silicon, a polycrystalline silicon, and the like.

The active layer ACT may include a source area, a drain area, and a channel area CHA located between the source area and the drain area.

In an embodiment, the source area and the drain area of the active layer ACT may include a conductive area CA. A second hole H2 exposing the first hole H1 may be defined in the conductive area CA. In an embodiment, the second hole H2 may overlap the first hole H1 (e.g., in the third direction DR3) and together with the first hole H1, may expose at least a portion of the upper surface of the etch stop layer ESL.

The conductive area CA may be an area doped with an impurity. In an embodiment, the conductive area CA may be doped with an N-type impurity. Alternatively, the conductive area CA may be doped with p-type impurities. By doping the conductive area CA with the impurity, the active layer ACT may be electrically connected to the contact electrode CTE. However, the channel area CHA may be a non-doped area or an area doped at a lower concentration than the conductive area CA.

The gate insulation layer GI may be disposed on the active layer ACT (e.g., disposed directly thereon in the third direction DR3). For example, the gate insulation layer GI may cover each of the third buffer layer BUF3 and the active layer ACT. A third hole H3 exposing the second hole H2 and a portion of the upper surface of the etch stop layer ESL may be defined in the gate insulation layer GI and overlapping with the first hole H1 and the second hole H2 (e.g., in the third direction DR3). The first to third holes H1, H2, and H3 may form one hole H.

In an embodiment, the gate insulation layer GI may include an inorganic insulation material. The gate insulation layer GI may have a structure including a single-layer or multi-layer inorganic insulation material.

The gate electrode GE may be disposed on the gate insulation layer GI (e.g., disposed directly thereon in the third direction DR3). The gate electrode GE may overlap the channel area CHA of the active layer ACT (e.g., in the third direction DR3). In an embodiment, the gate electrode GE may include a first conductive layer GE1, a second conductive layer GE2, and a third conductive layer GE3. The first conductive layer GE1 may be disposed on the gate insulation layer GI (e.g., disposed directly thereon in the third direction DR3). The second conductive layer GE2 may be disposed on the first conductive layer GEL (e.g., disposed directly thereon in the third direction DR3). The third conductive layer GE3 may be disposed on the second conductive layer GE2 (e.g., disposed directly thereon in the third direction DR3). For example, the gate electrode GE may have a triple-layer structure including three conductive layers consecutively stacked (e.g. in the third direction DR3).

In an embodiment, each of the first to third conductive layers GE1, GE2, and GE3 may include different materials from each other. For example, in an embodiment the first conductive layer GE1 may include a titanium, the second conductive layer GE2 may include a copper, and the third conductive layer GE3 may include a indium tin oxide (ITO). However, embodiments of the present disclosure are not necessarily limited thereto, and two or more gate electrodes of the first to third conductive layers GE1, GE2, and GE3 may include a same material as each other. In addition, an embodiment shown in FIG. 5, the gate electrode GE is shown as having a triple-layer structure. However the gate electrode GE may have a single-layer structure or a multi-layer structure including two or four or more conductive layers in some embodiments.

In an embodiment, the contact electrode CTE may be disposed on the gate insulation layer GI. For example, the contact electrode CTE may be disposed on the same layer as the gate electrode GE. In addition, the contact electrode CTE may include the same material as the gate electrode GE.

In an embodiment, the contact electrode CTE may include a first contact electrode CTE1 and a second contact electrode CTE2. In an embodiment in which the gate electrode GE has a triple-layer structure, each of the first contact electrode CTE1 and the second contact electrode CTE2 may have a triple-layer structure including three conductive layers. For example, in an embodiment the first contact electrode CTE1 may include a (1-1)th conductive layer CTE1-1, a (1-2)th conductive layer CTE1-2, and a (1-3)th conductive layer CTE1-3. The second contact electrode CTE2 may include a (2-1)th conductive layer CTE2-1, a (2-2)th conductive layer CTE2-2, and a (2-3)th conductive layer CTE2-3.

The first contact electrode CTE1 may be electrically connected to the active layer ACT. For example, in an embodiment the (1-1)th conductive layer CTE1-1 may directly contact the conductive area CA of the active layer ACT and the first contact electrode CTE1 may be electrically connected to the conductive area CA of the active layer ACT.

The first contact electrode CTE1 may be electrically connected to the light blocking layer BML. For example, in an embodiment the (1-1)th conductive layer CTE1-1 may directly contact the light blocking layer BML through a first contact hole CNT1 to be electrically connected to the light blocking layer BML. As the first contact electrode CTE1 is electrically connected to the light blocking layer BML, the light blocking layer BML may have a same voltage as the first contact electrode CTE1.

The first contact hole CNT1 may be a hole penetrating the first buffer layer BUF1, the second buffer layer BUF2, the etch stop layer ESL, the third buffer layer BUF3, and the gate insulation layer GI in the third direction DR3.

In an embodiment, the first contact electrode CTE1 may include a molybdenum, an aluminum, a chromium, a gold, a titanium, a nickel, a neodymium, a copper, and the like. These materials may be used alone or in combination with each other. However, embodiments of the present disclosure are not necessarily limited thereto.

The second contact electrode CTE2 may be electrically connected to the active layer ACT. For example, in an embodiment the (2-1)th conductive layer CTE2-1 direct contacts the conductive area CA of the active layer ACT and the second contact electrode CTE2 may be electrically connected to the conductive area CA of the active layer ACT.

The second contact electrode CTE2 may be electrically connected to the driving voltage line VDL. For example, in an embodiment the (2-1)th conductive layer CTE2-1 may directly contact the driving voltage line VDL through a second contact hole CNT2 and the second contact electrode CTE2 may be electrically connected to the driving voltage line VDL. As the second contact electrode CTE2 is electrically connected to the driving voltage line VDL, the driving voltage line VDL may have the same voltage as the second contact electrode CTE2.

The second contact hole CNT2 may be a hole penetrating the first buffer layer BUF1, the second buffer layer BUF2, the etch stop layer ESL, the third buffer layer BUF3, and the gate insulation layer GI in the third direction DR3

In an embodiment, the second contact electrode CTE2 may include substantially the same material as the first contact electrode CTE1. In addition, the second contact electrode CTE2 may be disposed on the same layer as the first contact electrode CTE1.

In an embodiment, the hole H may be located between the gate electrode GE and the contact electrode CTE (e.g., in the first direction DR1). For example, the first to third holes H1, H2, and H3 adjacent to the first contact electrode CTE1 may be located between the gate electrode GE and the first contact electrode CTE1. In addition, the first, second, and third holes H1, H2, and H3 adjacent to the second contact electrode CTE2 may be located between the gate electrode GE and the second contact electrode CTE2. For example, in an embodiment two or more holes H may be located on both sides of the gate electrode GE.

The inorganic layer PVX may be disposed on the gate insulation layer GI (e.g., disposed directly thereon). For example, the inorganic layer PVX may cover the gate insulation layer GI, the gate electrode GE, and the contact electrode CTE. The inorganic layer PVX may include an inorganic insulation material. For example, in an embodiment the inorganic insulation material may include a silicon oxide, a silicon nitride, a silicon oxynitride, and the like. These materials be used alone or in combination with each other. However, embodiments of the present disclosure are not necessarily limited thereto.

The via layer VIA may be disposed on the inorganic layer PVX (e.g., disposed directly thereon). The via layer VIA may include a substantially flat upper surface. The via layer VIA may include an organic insulation material. For example, in an embodiment the organic insulation material may include a photoresist, polyacrylic resin, a polyimide resin, an acrylic resin, and the like. These materials may be used alone or in combination with each other. However, embodiments of the present disclosure are not necessarily limited thereto.

The light-emitting element LED may be disposed on the via layer VIA (e.g., disposed directly thereon in the third direction DR3). For example, in an embodiment the light-emitting element LED may include an organic light-emitting element OLED, an inorganic light-emitting element, and the like. However, embodiments of the present disclosure are not necessarily limited thereto.

The pixel electrode PE may be disposed on the via layer VIA (e.g., disposed directly thereon in the third direction DR3). In an embodiment, the pixel electrode PE may be electrically connected to the first contact electrode CTE1 through a contact hole. The pixel electrode PE may transmit an electrical signal to the light-emitting layer EML. In an embodiment, the pixel electrode PE may include a metal, an alloy, a metal nitride, a conductive metal an oxide, a transparent conductive material, and the like. These materials may be used alone or in combination with each other.

In an embodiment, the first contact electrode CTE1 may be electrically connected to the light-emitting element LED. For example, in an embodiment the first contact electrode CTE1 may be electrically connected to the light-emitting element LED through the pixel electrode PE penetrating the via layer VIA and the inorganic layer PVX, so that a signal allowing the pixel PX to emit light may be transmitted.

The light-emitting layer EML may be disposed on the pixel electrode PE. In an embodiment, each light-emitting layer EML may emit light of at least one color among a blue, a red, and a green. However, embodiments of the present disclosure are not necessarily limited thereto. For example, in some embodiment the light-emitting layer EML may emit a color that is a combination of the blue, the red, and the green. The light-emitting layer EML may include organic light-emitting materials, quantum dots, and the like. However, embodiments of the present disclosure are not necessarily limited thereto.

The pixel define layer PDL may be disposed on the via layer VIA (e.g., disposed directly thereon in the third direction DR3). For example, the pixel define layer PDL may partially cover the pixel electrode PE. In addition, an opening that exposes at least a portion of the pixel electrode PE may be defined in the pixel define layer PDL. For example, in an embodiment the opening of the pixel define layer PDL may expose a central portion of the pixel electrode PE (e.g., in the first direction DR1), and the pixel define layer PDL may cover edges of the pixel electrode PE, such as lateral edges of the pixel electrode PE.

The pixel define layer PDL may include an inorganic material or an organic material. In an embodiment, the pixel define layer PDL may include an organic material such as an epoxy resin, a siloxane resin, and the like. These materials may be used alone or in combination with each other. However, embodiments of the present disclosure are not necessarily limited thereto. In some embodiments, the pixel define layer PDL may further include a light blocking material including a black pigment, a black dye, and the like.

The common electrode CE may be disposed on the light-emitting layer EML and the pixel define layer PDL. The common electrode CE may be disposed on the front surface of the display area. In an embodiment, the common electrode CE may include a metal, an alloy, a metal nitride, a conductive metal oxide, a transparent conductive material, and the like. These materials may be used alone or in combination with each other.

The encapsulation layer TFE may be disposed on the light-emitting element LED (e.g., disposed directly thereon in the third direction DR3). For example, the encapsulation layer TFE may be disposed on the common electrode CE (e.g., directly thereon in the third direction DR3). The encapsulation layer TFE may include at least one inorganic encapsulation layer and at least one organic encapsulation layer. The encapsulation layer TFE may prevent an oxygen and a moisture from penetrating into the light-emitting element LED.

In an embodiment, a color conversion layer may be disposed on the encapsulation layer TFE (e.g., disposed directly thereon in the third direction DR3). The color conversion layer may include a quantum dot. Electrons included in the quantum dot may transition from the conduction band to the valence band due to incident light incident on the quantum dot, and accordingly, the quantum dot may emit a specific color. However, embodiments of the present disclosure are not necessarily limited thereto.

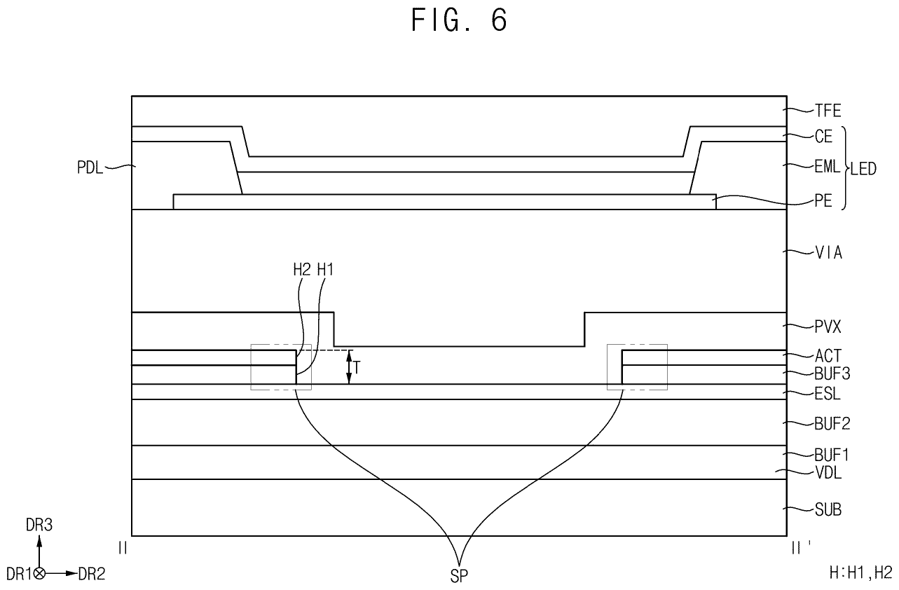

FIG. 6 is a cross-sectional view illustrating a cross-section taken along a line II-II′ of FIG. 4. FIG. 6 is a cross-sectional view illustrating a cross-section taken the pixel PX along the second direction DR2.

Referring to FIG. 6, the inorganic layer PVX may be disposed on the active layer ACT (e.g., disposed directly thereon). For example, the inorganic layer PVX may cover the active layer ACT and may directly contact the conductive area CA. The cross-sectional view of FIG. 6 may illustrate an area where a portion of each of the gate insulation layer (e.g., the gate insulation layer GI of FIG. 5) and the gate electrode (e.g., the gate electrode GE of FIG. 5) on the active layer ACT is removed and the first and second holes H1, H2 are formed.

The active layer ACT and the third buffer layer BUF3 may be disposed on the etch stop layer ESL (e.g., consecutively disposed thereon in the third direction DR3). The first hole H1 exposing a portion of the upper surface of the etch stop layer ESL is defined in the active layer ACT, and the second hole H2 exposing a portion of the upper surface of the etch stop layer ESL is defined in the third buffer layer BUF3. Unlike FIG. 5, FIG. 6 may illustrate an area where the gate insulation layer is not disposed, so the inorganic layer PVX may directly contact the etch stop layer ESL through the first hole H1 and the second hole H2.

The inorganic layer PVX may cover an end (e.g., lateral ends in the second direction DR2) of each of the active layer ACT and the third buffer layer BUF3 exposed by the first hole H1 and the second hole H2. The end of each of the active layer ACT and the third buffer layer BUF3 exposed by the first hole H1 and the second hole H2 may be defined as a step area SP. In an embodiment, in the step area SP, the inorganic layer PVX is formed on (e.g., formed directly thereon) and directly contacts an upper surface of the active layer ACT, a side surface (e.g., a sidewall) of the active layer ACT, a side surface (e.g., a sidewall) of the third buffer layer BUF3, and a portion of the upper surface of the etch stop layer ESL.

In an embodiment, a sum T of a depth of the first hole H1 and a depth of the second hole H2 may be less than or equal to about 30 nm. In an embodiment, the sum T of the depth of the first hole H1 and the depth of the second hole H2 may be less than or equal to about 20 nm. For example, a sum of the thicknesses of the active layer ACT and the third buffer layer BUF3 may be less than or equal to about 30 nm. In an embodiment, the sum of the thicknesses of the active layer ACT and the third buffer layer BUF3 may be less than or equal to about 20 nm.

However, when the sum T of the depth of the first hole H1 and the depth of the second hole H2 is greater than about 30 nm, the inorganic layer PVX filling the end of each of the active layer ACT and the third buffer layer BUF3 exposed by the first hole H1 and the second hole H2 may not have a uniform thickness. Accordingly, a moisture permeable path through which external moisture flows into the inorganic layer PVX may be formed around the end, and accordingly, a defect may be generated in the display device (e.g., the display device DD of FIG. 1).

As described above, the display device may have an etch stop layer ESL disposed between the second buffer layer BUF2 and the third buffer layer BUF3 (e.g., in the third direction DR3) in which the first hole H1 is defined. As the first hole H1 does not penetrate the etch stop layer ESL in a thickness direction and exposes at least a portion of the upper surface of the etch stop layer ESL, formation of a moisture permeable path through which external moisture flows in the inorganic layer PVX fills the first hole H1 may be prevented. Accordingly, a defect in the display device may be prevented and a reliability of the display device may be increased.

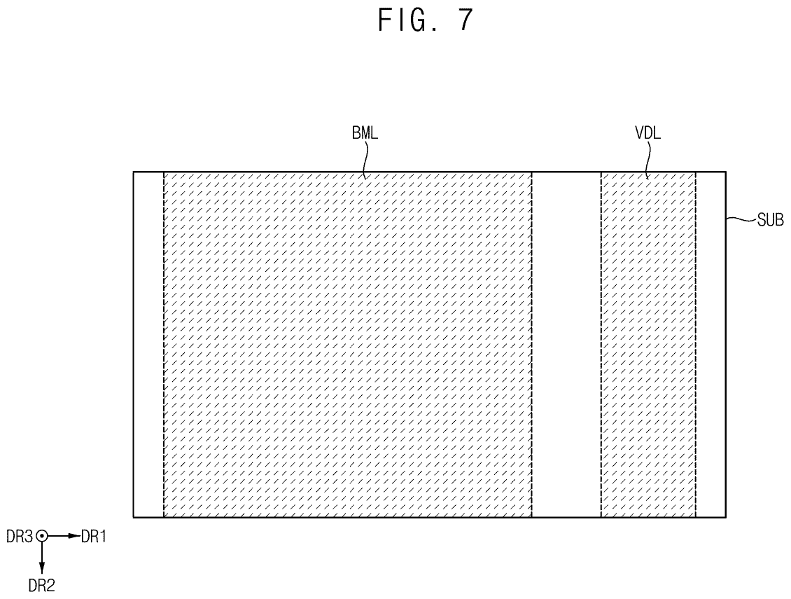

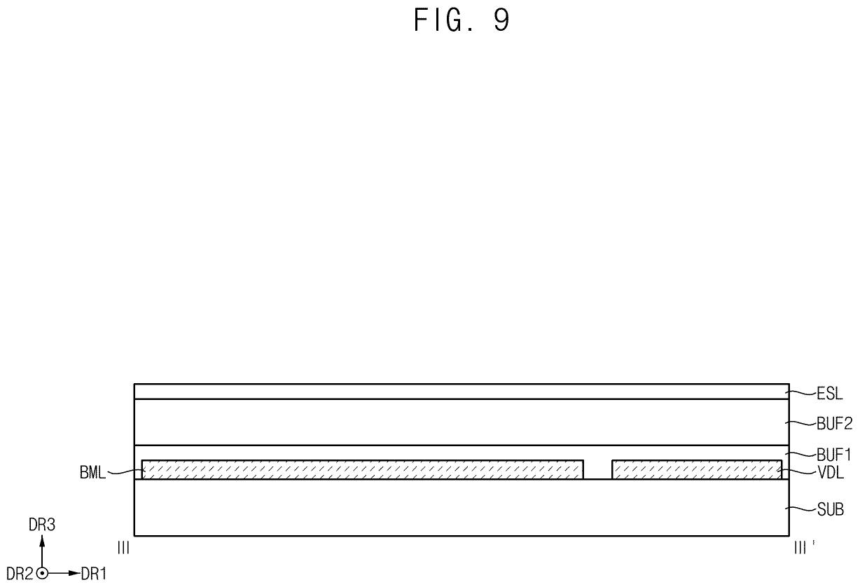

FIGS. 7, 8, 9, 10, 11, 12, 13, 14, 15, 16, 17, 18, 19, 20, 21, 22, and 23 are views for explaining a method of manufacturing the display device of FIG. 1. For example, FIGS. 7, 8, 10, 12, 13, 16, and 20 may be plan views illustrating areas corresponding to the pixel PX of FIGS. 9, 11, 14, 15, 17, 18, 19, 21, 22, and 23 may be cross-sectional views illustrating areas corresponding to the pixel PX.

Hereinafter, content that overlaps with the content described with reference to FIGS. 4 to 6 may be omitted or simplified for economy of explanation.

Referring to FIG. 7, in an embodiment the light blocking layer BML and the driving voltage line VDL may be formed on the substrate SUB (e.g., formed directly thereon in the third direction DR3). For example, each of the light blocking layer BML and the driving voltage line VDL may cover a portion of the substrate SUB. In addition, the light blocking layer BML and the driving voltage line VDL may include a same material as each other. In addition, the light blocking layer BML and the driving voltage line VDL may be disposed on a same layer as each other.

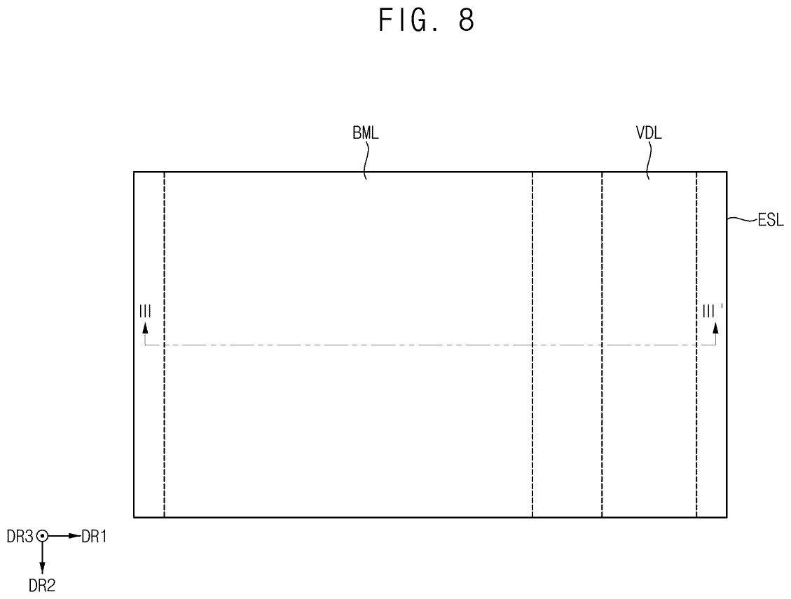

FIG. 9 is a cross-sectional view taken along line III-III′ of FIG. 8. Referring to FIGS. 8 and 9, in an embodiment the first buffer layer BUF1 may be formed on the light blocking layer BML and the driving voltage line VDL (e.g., formed directly thereon). The second buffer layer BUF2 may be formed on the first buffer layer BUF1 (e.g., formed directly thereon in the third direction DR3). For example, the first buffer layer may cover the light blocking layer BML, driving voltage line VDL, and substrate SUB. In addition, the second buffer layer BUF2 may cover the first buffer layer.

In an embodiment, the etch stop layer ESL may be formed on the second buffer layer BUF2 (e.g., formed directly thereon in the third direction DR3). For example, the etch stop layer ESL may cover the second buffer layer BUF2. In an embodiment, the etch stop layer ESL may include a different material from the second buffer layer BUF2.

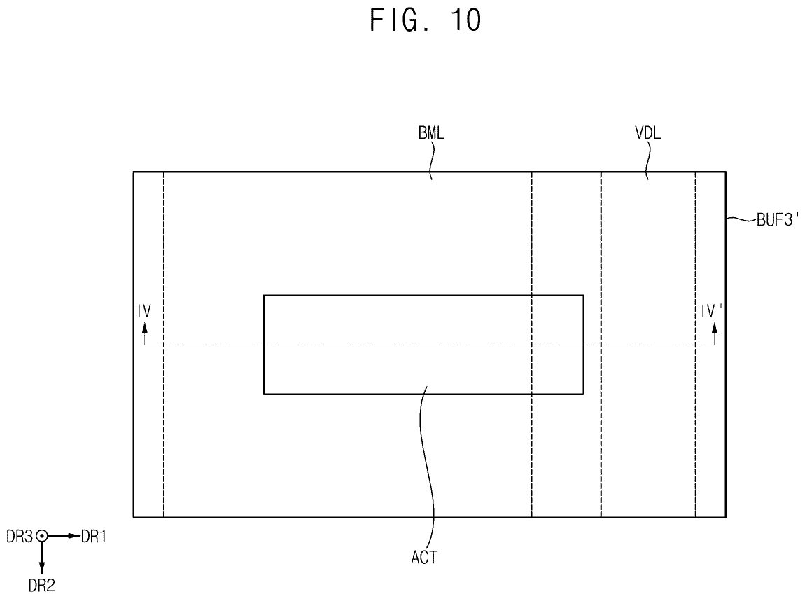

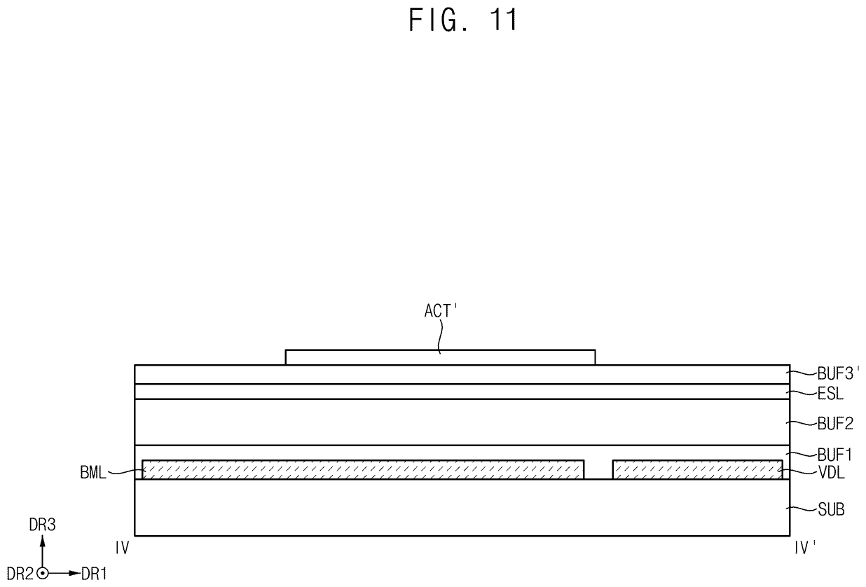

FIG. 11 is a cross-sectional view taken along line IV-IV′ of FIG. 10. Referring to FIGS. 10 and 11, a preliminary buffer layer BUF3′ may be formed on the etch stop layer ESL (e.g., formed directly thereon in the third direction DR3). A preliminary active layer ACT′ may be formed on the preliminary buffer layer BUF3′ (e.g., formed directly thereon in the third direction DR3). For example, the preliminary buffer layer BUF3′ may cover the etch stop layer ESL, and the preliminary active layer ACT′ may cover a portion of the preliminary buffer layer BUF3′.

The preliminary active layer ACT′ may correspond to the active layer ACT of FIG. 5. The preliminary active layer ACT′ may include a same material as the active layer ACT of FIG. 5. For example, in an embodiment the preliminary active layer ACT′ may include a metal oxide semiconductor, a silicon semiconductor, an organic semiconductor, and the like.

The preliminary active layer ACT′ may overlap a portion of the light blocking layer BML (e.g., in the third direction DR3). In addition, in an embodiment the preliminary active layer ACT′ may not overlap the driving voltage line VDL (e.g., in the third direction DR3). However, embodiments of the present disclosure are not necessarily limited thereto.

The preliminary buffer layer BUF3′ may correspond to the third buffer layer BUF3 of FIG. 5. In an embodiment, the preliminary buffer layer BUF3′ may include a different material from the etch stop layer ESL.

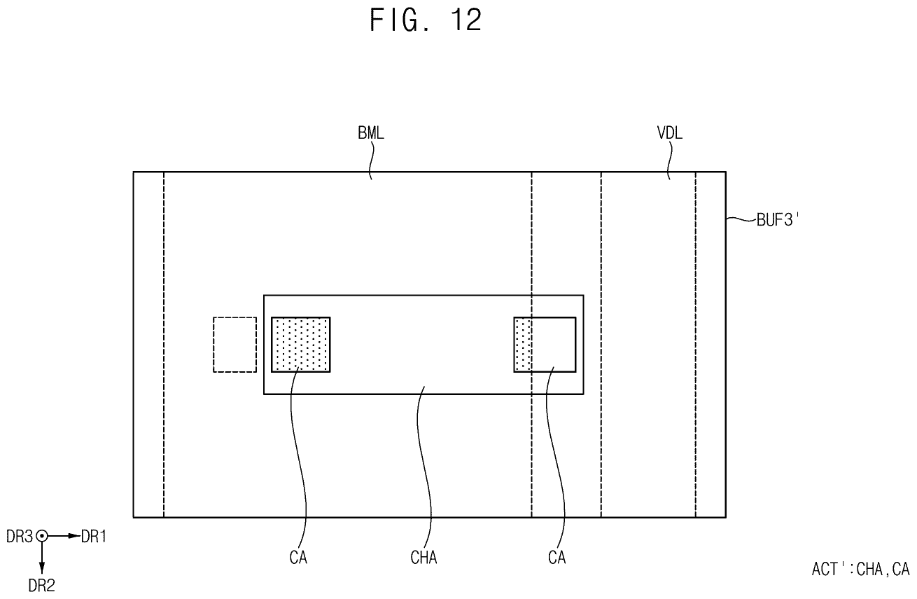

Referring to FIG. 12, the conductive area CA may be formed by doping a portion of the preliminary active layer ACT′ with impurities. For example, in an embodiment two conductive areas CA may be formed at positions adjacent to both ends of the preliminary active layer ACT′. A channel area CHA may be formed between the conductive areas CA. For example, in an embodiment, the channel area CHA may be formed between the conductive areas CA in the first direction DR1. However, embodiments of the present disclosure are not necessarily limited thereto.

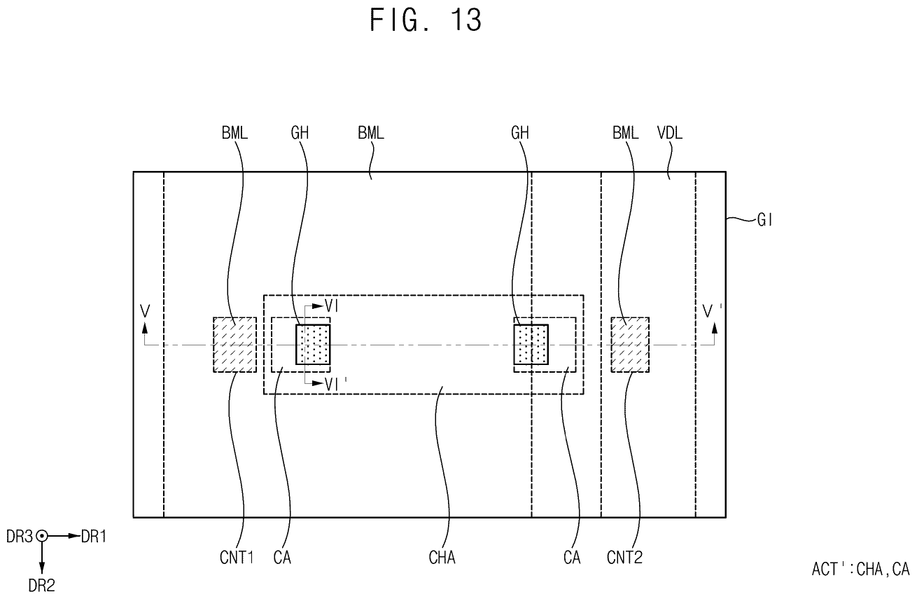

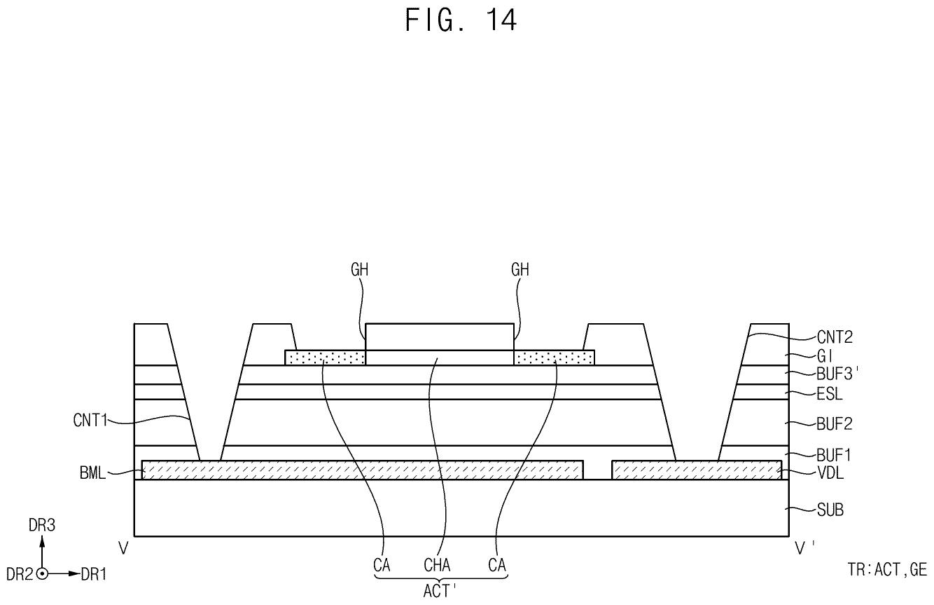

FIG. 14 is a cross-sectional view taken along line V-V′ that extends in the first direction DR1 of FIG. 13. Referring to FIGS. 13 and 14, the gate insulation layer GI may be formed on the preliminary active layer ACT′. For example, in an embodiment after the material forming the gate insulation layer GI is entirely applied on the preliminary active layer ACT′ and the preliminary buffer layer BUF′, a portion of the applied material is removed through an etching process to form the gate insulation layer. GI.

A gate hole GH may be defined in the gate insulation layer GI. For example, the gate hole GH exposing a portion of the upper surface of the conductive area CA may be defined in the gate insulation layer GI. In an embodiment, the gate hole GH may be located between the first contact hole CNT1 and the second contact hole CNT2 (e.g., in the first direction DR1). The gate hole GH may penetrate the gate insulation layer GI in the third direction DR3.

Each of the first contact hole CNT1 and the second contact hole CNT2 may be a hole penetrating the first buffer layer BUF1, the second buffer layer BUF2, the etch stop layer ESL, the preliminary buffer layer BUF3′, and the gate insulation layer GI in the third direction DR3.

In an embodiment, a portion of each of the first buffer layer BUF1, the second buffer layer BUF2, the etch stop layer ESL, the preliminary buffer layer BUF3′, and the gate insulation layer GI adjacent to the conductive area CA may be removed to define the first contact hole CNT1 exposing a portion of an upper surface of the light blocking layer BML in a plan view. A portion of each of the first buffer layer BUF1, the second buffer layer BUF2, the etch stop layer ESL, the preliminary buffer layer BUF3′, and the gate insulation layer GI adjacent to the conductive area CA may be removed to define the second contact hole CNT2 exposing a portion of an upper surface of the driving voltage line VDL in a plan view.

The preliminary active layer ACT′ may be located between the first contact hole CNT1 and the second contact hole CNT2 (e.g., in the first direction DR1).

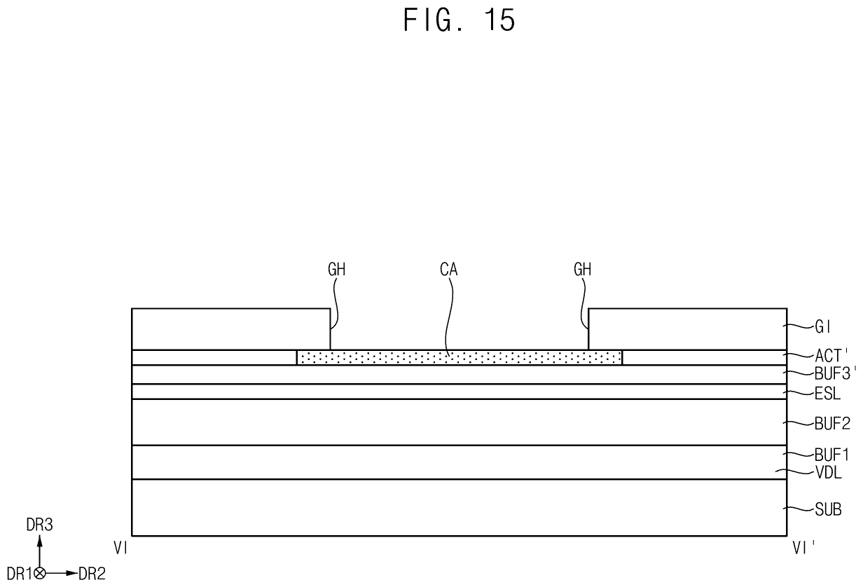

FIG. 15 is a cross-sectional view illustrating a cross-section of a portion of the components adjacent to the gate hole GH of FIG. 13 taken along a line VI-VI′ of FIG. 14 that extends in the second direction DR2.

Referring to FIG. 15, the gate hole GH exposing a portion of an upper surface of the preliminary active layer ACT′ may be defined. A portion of the conductive area CA may be exposed through the gate hole GH, and the other portion of the conductive area CA may be covered by the gate insulation layer GI.

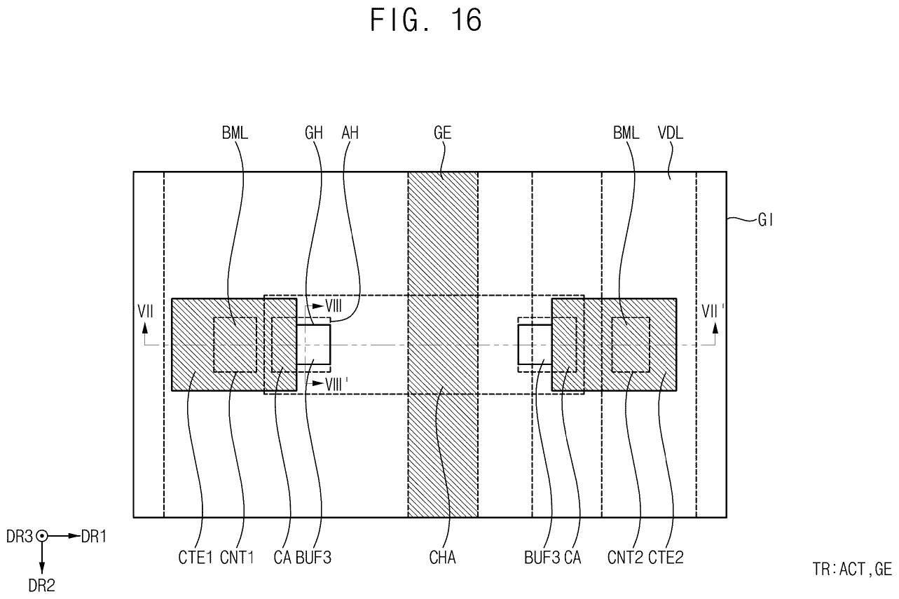

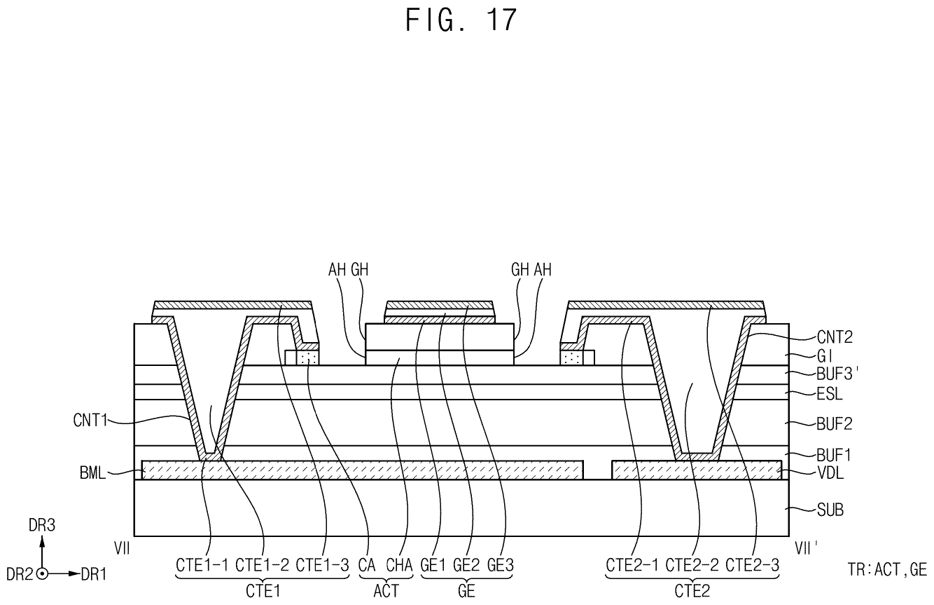

Referring to FIGS. 16 and 17, the gate electrode GE, the first contact electrode CTE1, and the second contact electrode CTE2 may be formed on the gate insulation layer GI. In an embodiment, a conductive material forming the gate electrode GE, the first contact electrode CTE1, and the second contact electrode CTE2 may be applied on the gate insulation layer GI to form a conductive layer. The conductive layer may be patterned to form the gate electrode GE, the first contact electrode CTE1, and the second contact electrode CTE2 on the gate insulation layer GI.

In an embodiment, the gate electrode GE, the first contact electrode CTE1, and the second contact electrode CTE2 may include a same material as each other. The gate electrode GE, the first contact electrode CTE1, and the second contact electrode CTE2 may be disposed on a same layer as each other.

In an embodiment, the conductive layer may have a triple layer structure. The three layers constituting the conductive layer may include different materials. Accordingly, the gate electrode GE may include the first, second, and third conductive layers GE1, GE2, and GE3 stacked in a triple-layer structure. In addition, the first contact electrode CTE1 may include (1-1)th, (1-2)th, and (1-3)th conductive layers CTE1-1, CTE1-2, and CTE1-3 stacked in a triple-layer structure. In addition, the second contact electrode CTE2 may include (2-1)th, (2-2)th, and (2-3)th conductive layers CTE2-1, CTE2-2, and CTE2-3 stacked in a triple-layer structure.

A portion of the preliminary active layer ACT′ of FIG. 14 may be removed to form the active layer ACT. An active hole AH exposing a portion of an upper surface of the preliminary buffer layer BUF3′ may be defined in the active layer ACT. The active hole AH may be a hole penetrating the conductive area CA of the active layer ACT.

The (1-1)th conductive layer CTE1-1 and the (2-1)th conductive layer CTE2-1 may directly contact the conductive area CA adjacent to the active hole AH. In addition, the (1-1)th conductive layer CTE1-1 may directly contact the light blocking layer BML, and the (2-1)th conductive layer CTE2-1 may directly contact the driving voltage line VDL. For example, the (1-1)th conductive layer CTE1-1 may simultaneously directly contact the light blocking layer BML and the conductive area CA. In addition, the (2-1)th conductive layer CTE2-1 may simultaneously directly contact the driving voltage line VDL and the conductive area CA.

The gate hole GH may be located between the first contact electrode CTE1 and the gate electrode GE (e.g., in the first direction DR1). As a portion of the gate hole GH of FIG. 17 is filled by the first contact electrode CTE1, a size of the gate hole GH may be less than a size of the gate hole GH of FIG. 14.

The gate hole GH may also be located between the second contact electrode CTE2 and the gate electrode GE (e.g., in the first direction DR1). As a portion of the gate hole GH of FIG. 17 is filled by the second contact electrode CTE2, a size of the gate hole GH may be less than a size of the gate hole GH of FIG. 14.

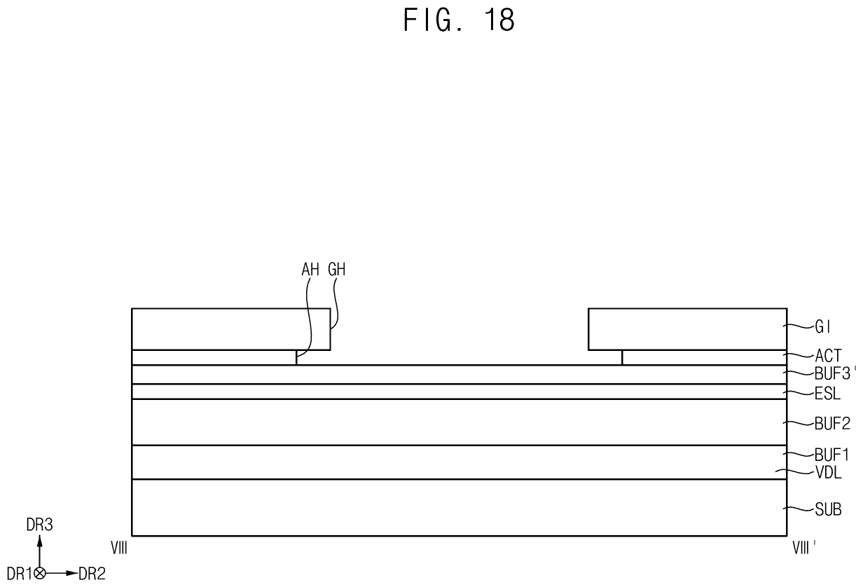

FIG. 18 is a cross-sectional view illustrating a cross-section of a portion of the components adjacent to the active hole AH of FIG. 16 taken along a line VIII-VIII′ of FIG. 16 extending in the second direction DR2.

Referring to FIG. 18, the conductive area (e.g., the conductive area CA of FIG. 15) of the active layer ACT is removed, the active hole AH exposing an upper surface of the preliminary buffer layer BUF′ may be defined.

In an embodiment, a size of the gate hole GH may be less than a size of the active hole AH. For example, in FIG. 17, which is a cross section cut along a line VII-VII′ of FIG. 16 that extends parallel to the first direction DR1, a boundary of the gate hole GH may coincide with a boundary of the active hole AH. However, in FIG. 18 which is a cross section cut along a line VIII-VIII′ of FIG. 16 extending in the second direction DR2, a width of the gate hole GH may be less than a width of the active hole AH. Accordingly, in a cross-sectional view, the active layer ACT may have an undercut shape together with the gate insulation layer GI.

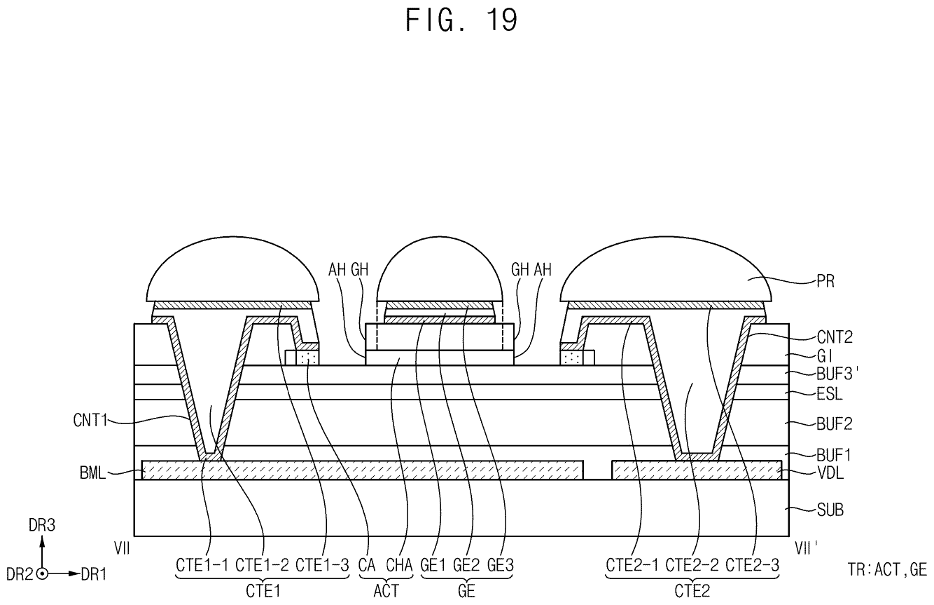

Referring to FIG. 19, a photoresist PR may be formed on (e.g., formed directly thereon in the third direction DR3) the gate electrode GE, the first contact electrode CTE1, and the second contact electrode CTE2. After the photoresist PR is formed, an etching process may be performed to remove a portion of each of the gate insulation layer GI and the preliminary buffer layer BUF3′.

In an embodiment, the photoresist PR may be a positive photoresist. For example, a portion of each of the gate insulation layer GI and the preliminary buffer layer BUF3′ that does not overlap the photoresist PR may be removed. Alternatively, the photoresist PR may be a negative photoresist. For example, a portion of each of the gate insulation layer GI and the preliminary buffer layer BUF3′ that overlap the photoresist PR may be removed.

In an embodiment, the etching process may be performed by spraying an etching gas on each of the gate insulation layer GI and the preliminary buffer layer BUF3′ to remove portions of the gate insulation layer GI and the preliminary buffer layer BUF3′ in the thickness direction. In an embodiment, the etching gas may include an octa-fluorobutene (C4F8), an oxygen (O2), an argon (Ar), and the like. These gases may be used alone or in combination. For example, the etching process may be a dry etching process.

However, in a comparative embodiment in which the preliminary buffer layer BUF3′ is formed directly on the second buffer layer BUF2 without including the etch stop layer ESL therebetween, the etching gas may be used after all reactions with the preliminary buffer layer BUF3′ are completed and may penetrate the second buffer layer BUF2 in a thickness direction.

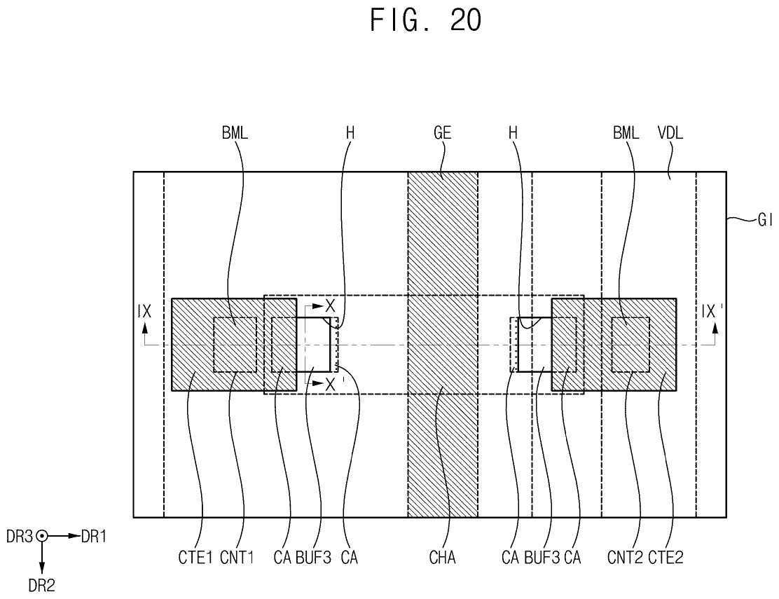

In an embodiment, the etching gas may be a gas with a lower etch selectivity for a material included in the etch stop layer ESL than a material included in the preliminary buffer layer BUF3′. For example, in a same process using the etching gas, an etch rate of the etch stop layer ESL may be less than the etch rate of the preliminary buffer layer BUF3′. Accordingly, while the preliminary buffer layer BUF3′ is removed and the first hole H1 of FIG. 20 is formed, the etch stop layer ESL may not be etched.

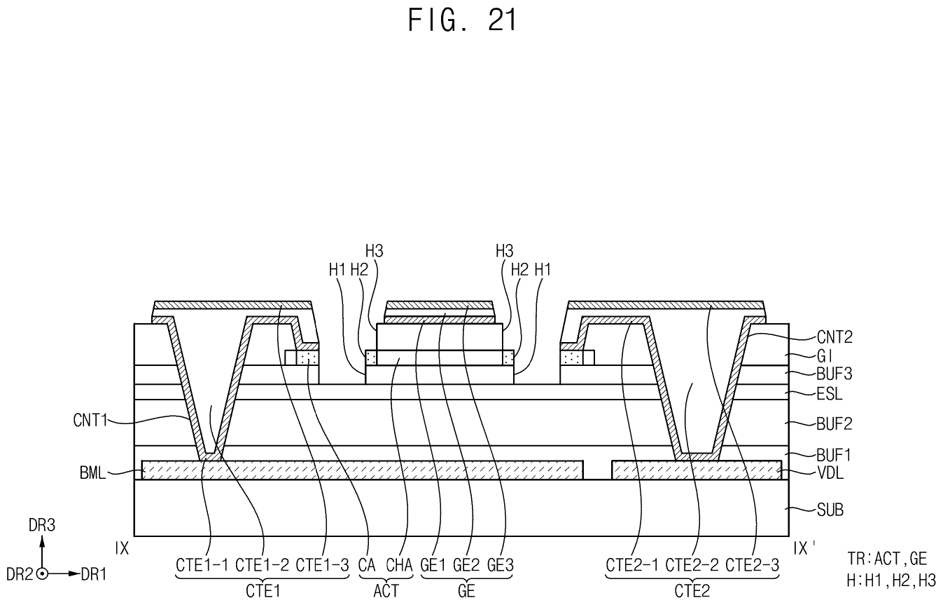

Referring to FIGS. 20 and 21, the photoresist PR of FIG. 19 disposed on the gate electrode GE, the first contact electrode CTE1, and the second contact electrode CTE2 may be removed.

A portion of the preliminary buffer layer BUF3′ in FIG. 19 may be removed to form the third buffer layer BUF3. The first hole H1 exposing a portion of the upper surface of the etch stop layer ESL may be defined in the third buffer layer BUF3. In addition, the second hole H2 may be defined in the active layer ACT, which is connected to the first hole H1 and exposes a portion of the upper surface of the etch stop layer ESL. The second hole H2 defined on the active layer ACT may correspond to the active hole AH of FIG. 19. In an embodiment, the forming of the first hole H1 may be performed after the forming of the second hole H2.

A third hole H3 may be defined in the gate insulation layer GI by extending the gate hole GH of FIG. 19 in the first direction DR1. In addition, as the gate hole GH of FIG. 19 expands, a portion of the gate insulation layer GI may be removed. The active layer ACT exposed by the removed gate insulation layer GI may be doped with impurities to form a conductive area CA. Each of the first to third holes H1, H2, and H3 may be connected to each other in the third direction DR3 to define the hole H exposing a portion of the upper surface of the etch stop layer ESL.

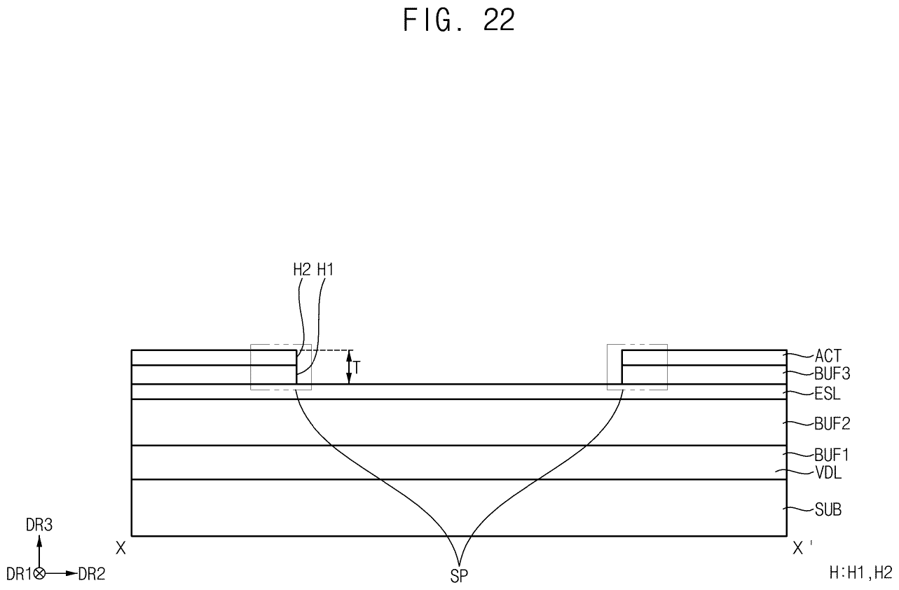

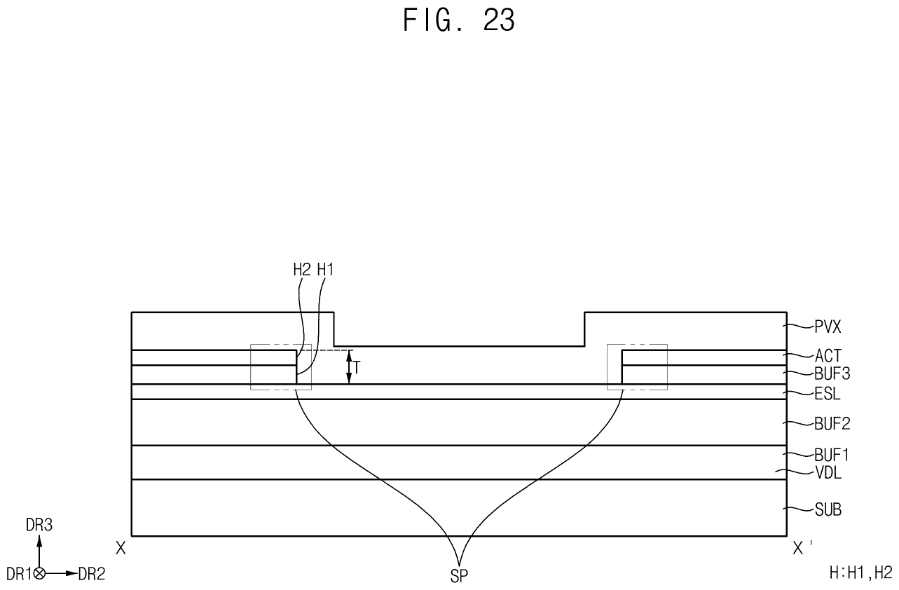

FIG. 22 is a cross-sectional view illustrating a cross-section taken a portion of the components adjacent to the hole H of FIG. 20 along a line parallel to the second direction DR2. FIG. 23 is a cross-sectional view illustrating a cross-section of the inorganic layer PVX added to cover a portion of each of the active layer ACT, the third buffer layer BUF3, and the etch stop layer ESL in the step area SP of FIG. 22.

Referring to FIG. 22, the step area SP may be defined around the first hole H1 and the second hole H2. In an embodiment, the sum T of the depth of the first hole H1 and the depth of the second hole H2 around the step area SP may be less than or equal to about 30 nm. For example, in an embodiment the sum T of the depth of the first hole H1 and the depth of the second hole H2 around the step area SP may be less than or equal to about 20 nm.

In an embodiment, the sum of the thicknesses of the active layer ACT and the third buffer layer BUF3 around the step area SP may be less than or equal to about 30 nm. In an embodiment, the sum of the thicknesses of the active layer ACT and the third buffer layer BUF3 around the step area SP may be less than or equal to about 20 nm.

Referring to FIG. 23, an inorganic layer PVX may be formed on the active layer ACT (e.g., formed directly thereon). The inorganic layer PVX may cover the gate insulation layer GI, the gate electrode GE, the first contact electrode CTE1, and the second contact electrode CTE2 of FIG. 21. However, the cross section of FIG. 23 may illustrate an area where the gate insulation layer GI, the gate electrode GE, the first contact electrode CTE1, and the second contact electrode CTE2 of FIG. 21 are removed on the active layer ACT.

The inorganic layer PVX may cover a portion of each of the active layer ACT, third buffer layer BUF3, and etch stop layer ESL in the step area SP. For example, in an embodiment the inorganic layer PVX may fill the first hole H1 and the second hole H2 and may cover each of the active layer ACT, third buffer layer BUF3, and etch stop layer ESL. For example, the inorganic layer PVX may cover upper and a side surface (e.g., sidewall) of the active layer ACT, a side surface (e.g., a sidewall) of the third buffer layer BUF3, and the upper surface of the etch stop layer ESL.

As described above, a reactivity of the etch stop layer ESL to the etching gas may be less than a reactivity of the preliminary buffer layer BUF′ to the etching gas. Accordingly, the first hole H1 may penetrate the third buffer layer BUF3, but may not penetrate the etch stop layer ESL. Accordingly, the defect in the display device may be prevented, and the reliability of the display device may be increased.

Referring further to FIG. 5, the via layer VIA, the light-emitting element LED, the pixel define layer PDL, and the encapsulation layer TFE may be sequentially formed on the inorganic layer PVX. Accordingly, the display device DD of FIGS. 4 and 5 may be manufactured.

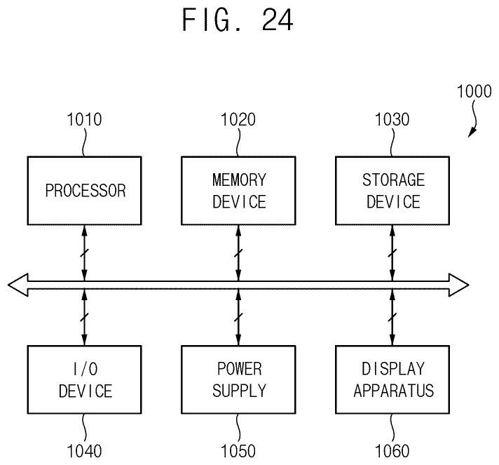

FIG. 24 is a block diagram illustrating an electronic device according to an embodiment.

Referring to FIG. 24, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

The display device and the method according to embodiments of the present disclosure may be applied to an electronic device included in a computer, a notebook, a mobile phone, a smartphone, a smart pad, a PMP, a PDA, an MP3 player, or the like.

Although the display device and the method according to non-limiting embodiments have been described with reference to the drawings, the illustrated embodiments are examples, and may be modified and changed by a person having ordinary knowledge in the relevant technical field without departing from the technical spirit of the present disclosure.

What is claimed is:

1. A display device comprising:
a first buffer layer disposed on a substrate;
an etch stop layer disposed on the first buffer layer;
a second buffer layer disposed on the etch stop layer, the second buffer layer including a first hole exposing at least a portion of an upper surface of the etch stop layer;
an active layer disposed on the second buffer layer, the active layer including a conductive area and a second hole exposing the first hole; and
an inorganic layer disposed on the active layer, the inorganic layer filling the first hole and the second hole.

2. The display device of claim 1, wherein the etch stop layer includes a material different from a material of the second buffer layer.

3. The display device of claim 2, wherein the etch stop layer includes at least one compound selected from a group consisting of a metal oxide, a silicon (Si), a silicon nitride (SiNₓ), and a silicon oxynitride (SiNₓO_{y}).

4. The display device of claim 2, wherein the second buffer layer includes a silicon oxide (SiOₓ).

5. The display device of claim 2, wherein:
the first buffer layer includes a third buffer layer disposed on the substrate and a fourth buffer layer disposed on the etch stop layer; and
the etch stop layer includes a material different from a material of the fourth buffer layer.

6. The display device of claim 5, wherein the fourth buffer layer includes a silicon oxide.

7. The display device of claim 1, wherein a sum of a depth of the first hole and a depth of the second hole is less than or equal to about 30 nm.

8. The display device of claim 1, wherein the etch stop layer directly contacts the inorganic layer through the first hole and the second hole.

9. The display device of claim 1, wherein the inorganic layer covers an end of the active layer that is exposed by the first hole and the second hole, and an end of the second buffer layer.

10. The display device of claim 9, wherein around the end of the active layer and the end of the second buffer layer,
the inorganic layer directly contacts an upper surface of the active layer, a side surface of the active layer, a side surface of the second buffer layer, and a portion of the upper surface of the etch stop layer.

11. The display device of claim 1, further comprising:
a gate insulation layer disposed on the active layer;
a gate electrode disposed on the gate insulation layer; and
a contact electrode disposed on the gate insulation layer and directly contacting a portion of the conductive area.

12. The display device of claim 11, wherein:
the gate insulation layer includes a third hole exposing the second hole and a portion of an upper surface of the active layer; and
a size of the third hole is greater than a size of the second hole.

13. The display device of claim 11, wherein each of the first hole and the second hole is located between the gate electrode and the contact electrode.

14. A method of manufacturing a display device, the method comprising:
forming a first buffer layer on a substrate;
forming an etch stop layer on the first buffer layer;
forming a second buffer layer on the etch stop layer, the second buffer layer including a first hole exposing a portion of an upper surface of the etch stop layer;
forming an active layer on the second buffer layer, the active layer including a second hole exposing the first hole; and
forming an inorganic layer on the active layer, the inorganic layer filling the first hole and the second hole.

15. The method of claim 14, wherein:
the forming of the second buffer layer includes:
forming a preliminary buffer layer on the etch stop layer; and
forming the first hole by removing a portion of the preliminary buffer layer, and
the forming of the active layer includes:
forming a preliminary active layer on the preliminary buffer layer; and
forming the second hole by removing a portion of the preliminary active layer.

16. The method of claim 15, wherein the forming of the first hole includes:
removing a portion of the preliminary buffer layer in a thickness direction to expose the upper surface of the etch stop layer by spraying an etching gas on the preliminary buffer layer.

17. The method of claim 15, wherein the forming of the first hole is performed after the forming of the second hole.

18. The method of claim 17, further comprising:
forming a gate insulation layer on the preliminary active layer, the gate insulation layer including a gate hole exposing a portion of an upper surface of preliminary active layer;
forming a gate electrode on the gate insulation layer; and
forming a contact electrode on the gate insulation layer, the contact electrode is spaced apart from the gate electrode.

19. The method of claim 18, wherein a size of gate hole is less than a size of the second hole.

20. The method of claim 18, further comprising:
forming a third hole by expanding the gate hole,
wherein a size of the third hole is greater than a size of the second hole.

21. An electronic device comprising:
a display device; and
a power supply configured to provide power to the display device,
wherein the display device comprises:
a first buffer layer disposed on a substrate;
an etch stop layer disposed on the first buffer layer;
a second buffer layer disposed on the etch stop layer, the second buffer layer including a first hole exposing at least a portion of an upper surface of the etch stop layer;
an active layer disposed on the second buffer layer, the active layer including a conductive area and a second hole exposing the first hole; and
an inorganic layer disposed on the active layer, the inorganic layer filling the first hole and the second hole.
